(19) United States
(12) Patent Application Publication
(10) Pub. No.: US 2009/0156012 A1
(43) Pub. Date: Jun. 18, 2009

(54) METHOD FOR FABRICATING LOW K DIELECTRIC DUAL DAMASCENE STRUCTURES

(75) Inventors: CHANG-LIN HSIEH, San Jose, CA (US); BINXI GU, San Jose, CA (US); JIE YUAN, San Jose, CA (US); HUI XIONG DAI, San Jose, CA (US); ROBIN CHEUNG, Cupertino, CA (US); SUBHASH DESHMUKH, San Jose, CA (US)

Correspondence Address: MOSER IP LAW GROUP / APPLIED MATERIALS, INC., 1030 BROAD STREET, 2ND FLOOR, SHREWSBURY, NJ, 07702, US

(73) Assignee: APPLIED MATERIALS, INC., Santa Clara, CA (US)

(21) Appl. No.: 11/954,550

(22) Filed: Dec. 12, 2007

(51) Int. Cl. H01L 21/461

(52) U.S. Cl. 438/719; 438/710; 257/E21.483

(57) ABSTRACT

Methods for forming dual damascene structures in low-k dielectric materials that facilitate reducing photoresist poison issues are provided herein. In some embodiments, such methods may include plasma etching a via through a first mask layer into a low-k dielectric material disposed on a substrate. The first mask layer may then be removed using a process including exposing the first mask layer to a first plasma comprising an oxygen containing gas and at least one of a dilutant gas or a passivation gas, and subsequently exposing the first mask layer to a second plasma comprising an oxygen containing gas and formed using one of either plasma bias power or plasma source power. An anti-reflective coating may then be deposited into the via and atop the low-k dielectric material. A trench may then be plasma etched through a second mask layer formed atop the anti-reflective coating into the low-k dielectric material.

### BACKGROUND

1. Field

The present invention generally relates to dual damascene structures for integrated circuits, and, more particularly, to methods for forming dual damascene structures comprising dielectric materials having low dielectric constants (low-k).

2. Description of Related Art

In the field of semiconductor device fabrication, as device feature sizes decrease to 0.18 μm and smaller, RC delay of interconnects becomes a major limiting factor for device speed. Two areas of development focus on this problem. First, the interconnect conductor resistance is being reduced by the use of copper and other conductors having a lower resistance than aluminum, which has been the industry standard for conductive interconnect material. In the second area, the interconnect contribution to the capacitance is being reduced by the use of dielectric materials having a lower dielectric constant (k) than silicon dioxide (about 3.9), which has been the industry standard dielectric.

Unfortunately, low-k dielectric materials are not easy to process using some conventional dual damascene techniques. In particular, low-k dielectric materials are susceptible to damage during plasma processing, such as plasma etching techniques used to strip mask layers after the low-k dielectric layer has been etched. The damaged surface of the low-k dielectric materials typically has different optical properties than an undamaged surface. This change in the optical properties of the damaged surface can lead to variations in the critical dimension (CD) upon exposure of a resist material deposited atop the low-k material and/or result in underexposed resist material that can not easily be removed. The underexposed, and unremoved, resist material is one example of photoresist (PR) scumming. Furthermore, PR poisoning is another example of a process that can lead to PR scumming. In PR poisoning, the presence of residual amine materials, due to one or more process conditions in the fabrication of a dual damascene structure, poison the resist material by blocking the photo acid generator (PAG) during exposure and development of the mask layer. Thus, PR poisoning results in a layer of undeveloped resist which is another example of PR scumming.

Thus, there is a need for a method to reduce PR scumming in the fabrication of dual damascene structures.

### SUMMARY

Methods for forming dual damascene structures in low-k dielectric materials that facilitate reducing photoresist poison issues are provided herein. In some embodiments, such methods may include plasma etching a via through a first mask layer into a low-k dielectric material disposed on a substrate. The first mask layer may then be removed using a process including exposing the first mask layer to a first plasma comprising an oxygen containing gas and at least one of a dilutant gas or a passivation gas, and subsequently exposing the first mask layer to a second plasma comprising an oxygen containing gas and formed using one of either plasma bias power or plasma source power. An anti-reflective coating may then be deposited into the via and atop the low-k dielectric material. A trench may then be plasma etched through a second mask layer formed atop the anti-reflective coating into the low-k dielectric material.

In some embodiments, such a method may include plasma etching a via through a first mask layer into a low-k dielectric material disposed on a substrate using a plasma formed from a process gas mixture comprising a fluorocarbon gas, a nitrogen-containing gas, and an inert gas. The first mask layer may then be removed using a process including exposing the first mask layer to a first plasma comprising an oxygen-containing gas and at least one of a dilutant gas or a passivation gas and subsequently exposing the first mask layer to a second plasma comprising an oxygen-containing gas and formed using one of either plasma bias power or plasma source power. An anti-reflective coating may then be deposited into the via and atop the low-k dielectric material. A trench may then be etched through a second mask layer formed atop the anti-reflective coating into the low-k dielectric material using a plasma formed from a process gas mixture comprising a fluorine-containing gas, a nitrogen-containing gas, and an inert gas.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a flow chart of a method of etching dual damascene structures in accordance with some embodiments of the present invention.

FIGS. 2A-J depict stages of fabrication of a dual damascene structure in accordance with embodiments of the method of FIG. 1.

FIG. 3 depicts an etch reactor suitable for performing portions of the present invention.

To facilitate understanding, identical reference numerals have been used, where possible, to designate identical elements that are common to the figures. The above drawings are not to scale and may be simplified for illustrative purposes.

### DETAILED DESCRIPTION OF THE DRAWINGS

Embodiments of the present invention provide methods for the fabrication of dual damascene interconnect structures in low-k dielectric materials. Embodiments of the present invention may advantageously limit photoresist scumming or poisoning that can occur during the fabrication of a low-k dielectric dual damascene structure.

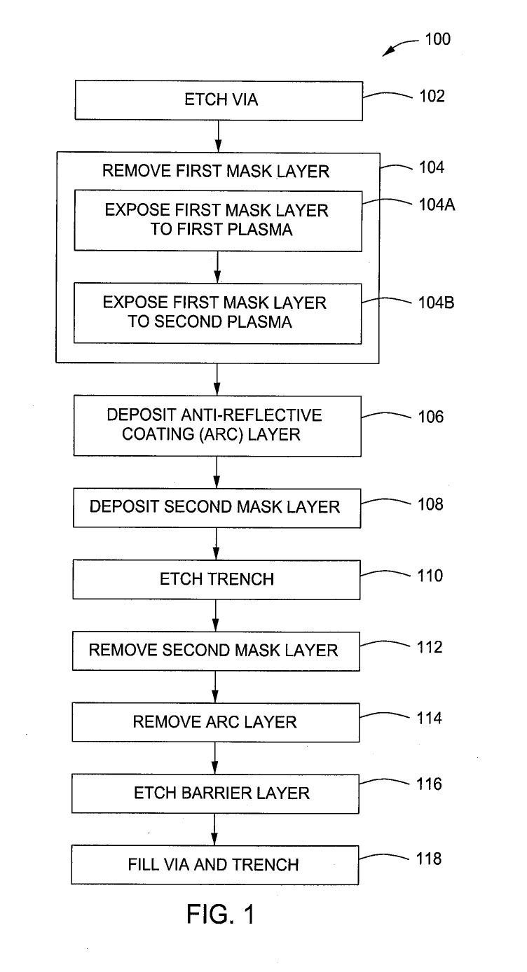

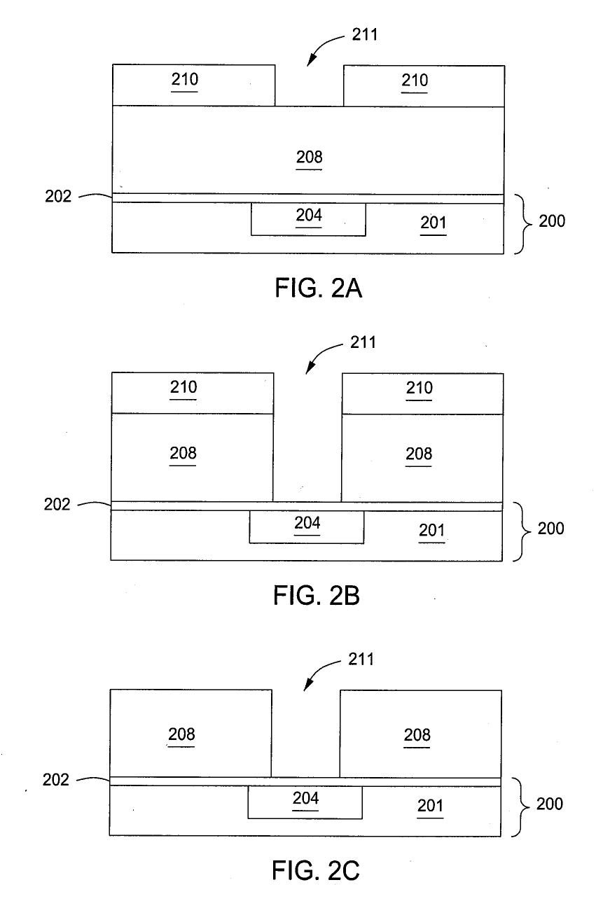

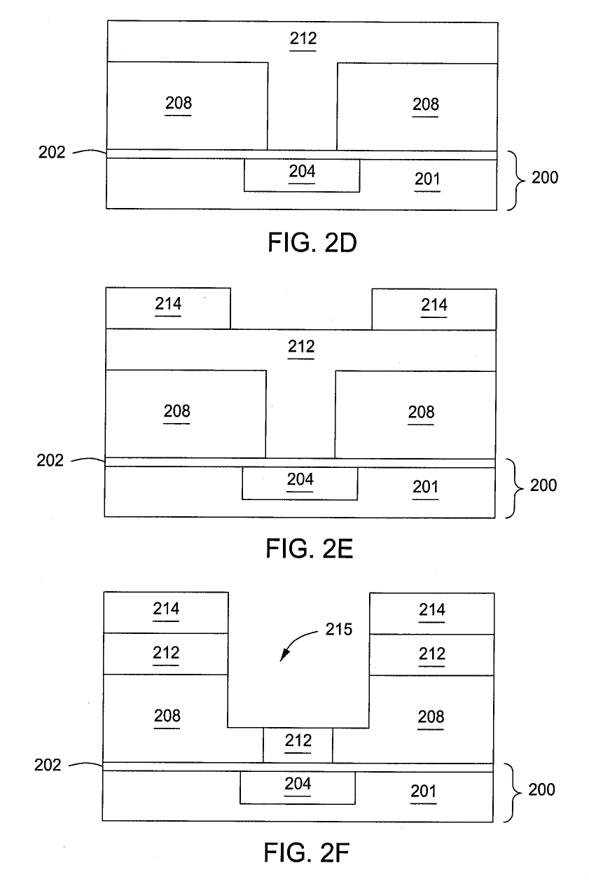

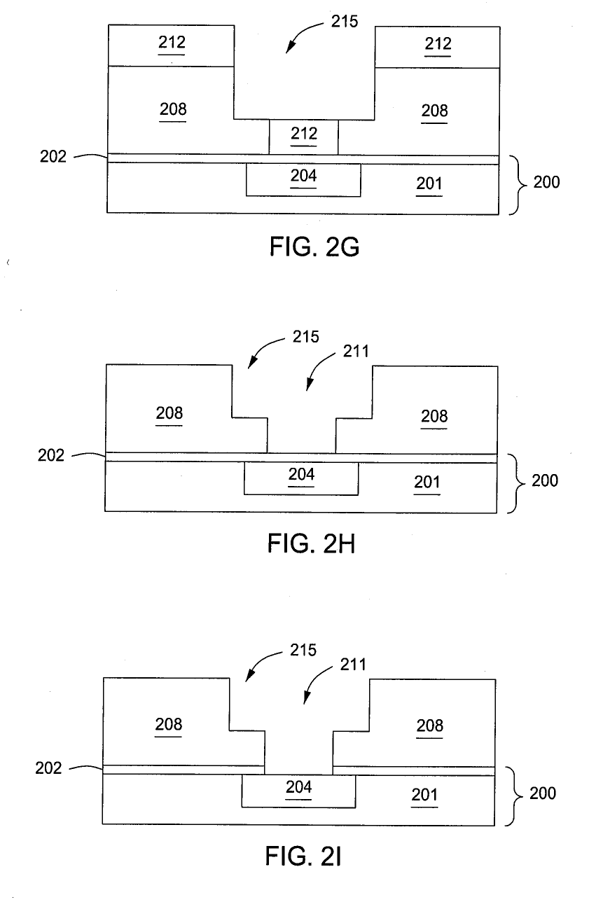

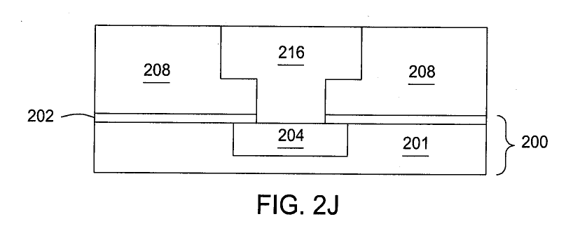

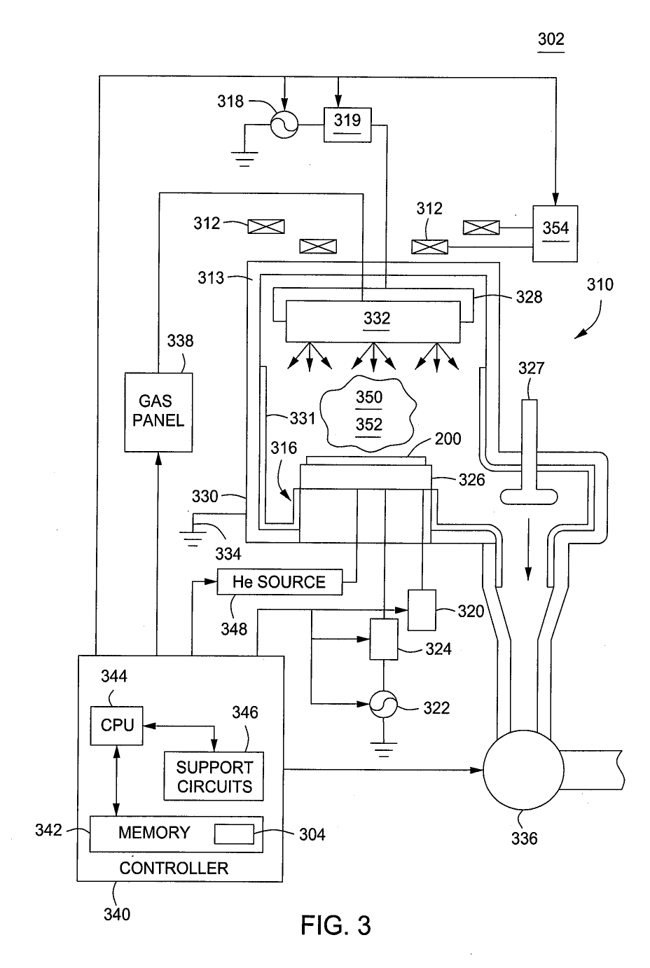

FIG. 1 depicts a method 100 for fabricating dual damascene interconnect structures in accordance with some embodiments of the present invention. The method 100 is described with reference to FIGS. 2A-F, which depicts respective stages of fabrication of the dual damascene structure corresponding to the method of FIG. 1. The method 100 may be performed in any suitable etch chamber, such as the ENABLER® process chamber, available from Applied Materials, Inc. of Santa Clara, Calif., or other suitable etch chamber, such as described below with respect to FIG. 3. The etch chamber may be part of a cluster tool, such as one of the CENTURA® line of cluster tools, also available from Applied Materials, Inc.

FIGS. 2A-J depict illustrative schematic representations of the fabrication steps of a dual damascene interconnect structure on a substrate 200. The substrate 200 may comprise a semiconductor substrate and may include fully or partially formed layers and/or devices formed therein or thereupon. For example, in some embodiments, and as depicted in FIG. 2A, the substrate 200 may have a barrier layer 202 disposed on top of a metal interconnect structure 204 formed in a low-k dielectric layer 201. The barrier layer 202 may comprise any suitable layer of material, such as silicon nitride (SiN), silicon carbide (SiC), nitrogen doped silicon carbide (SiNC), oxygen and nitrogen doped silicon carbide (SiONC), or the like. The metal interconnection structure 204 may comprise a conductive material, such as a metal, for example copper (Cu), gold (Au), aluminum (Al), or the like. The metal interconnect structure 204 may have an upper surface that is substantially coplanar or flush with an upper surface of the low-k dielectric layer 201. A low-k dielectric layer 208 may deposited on top of the substrate 200 (e.g., on top of the low-k dielectric layer 201, or the barrier layer 202 when present, or any other layer that may be present on the substrate 200). The low-k dielectric layer 208 may be any organic, low-k dielectric material having a dielectric constant that is less than the dielectric constant of silicon dioxide (SiO₂), which is about 3.9. For example, the organic material may be a carbon doped oxide (such as Black Diamond or Black Diamond II, available from Applied Materials), a polymer-based low-k dielectric material (such as SiLK®, available from Dow Chemical Company), an organic polymer (such as FLARE™, a bridged poly-arylene ether available from Honeywell Advanced Microelectronic Materials), or the like. In some embodiments, a first mask layer 210, such as a photomask layer, may be formed atop the low-k dielectric layer 208 and patterned to define a via 211 to be etched into the low-k dielectric layer 208.

The method 100 begins at 102, where the via 211 is etched into the low-k dielectric layer 208, as shown in FIG. 2B. The via 211 may be etched down to the metal interconnect structure 204, or down to the barrier layer 202. In some embodiments, the via 211 may be etched into the low-k dielectric layer 208 using a plasma etch process that includes a process gas or process gas mixture comprising a fluorocarbon gas, a nitrogen-containing gas, and an inert gas. As used herein, the phrases “a process gas” and “a process gas mixture” are interchangeable and may include one or more gases. Optionally, a hydrofluorocarbon gas may also be provided. In some embodiments, the fluorocarbon gas may be hexafluoro-1,3-butadiene (C₄F₆), octafluorocyclobutane (C₄F₈), octafluorocyclopentene (C₅F₈), hexafluorobenzene (C₆F₆), tretrafluoromethane (CF₄), hexafluoroethane (C₂F₆), or the like. The nitrogen-containing gas may be nitrogen (N₂). The inert gas may comprise argon (Ar), helium (He), xenon (Xe), or other inert gases. The hydrofluorocarbon gas may be difluoromethane (CH₂F₂), trifluoromethane (CHF₃), methyl fluoride (CH₃F), or the like. In some embodiments, the process gas mixture may include C₄F₆, CH₂F₂, N₂, and Ar.

In some embodiments, the process gas mixture for the via etch may be supplied to the etch chamber at a total gas flow from about 260-1040 sccm. In some embodiments, the total gas flow may be between about 260-1040 sccm, and in one illustrative embodiment the total gas flow is about 625 sccm. In some embodiments, the process gas mixture may comprise between about 1.0-7.4 percent fluorocarbon gas (e.g., a fluorocarbon gas flow of between about 10-20 sccm). In some embodiments, the process gas mixture may comprise between about 0-7.1 percent hydrofluorocarbon gas (e.g., a hydrofluorocarbon gas flow of between about 0-20 sccm). In some embodiments, the process gas mixture may comprise between about 5.6-49.8 percent nitrogen-containing gas (e.g., a nitrogen-containing gas flow of between about 50-200 sccm). While not intending to be bound by theory, it is believed that limiting the amount of nitrogen gas provided during the etch process, advantageously reduces photoresist poisoning by reducing the amount of nitrogen or nitrogen-containing byproducts that may be remain on the surface of the via or elsewhere on the substrate or in the chamber and that may migrate to or otherwise interact with the photoresist or other materials during subsequent processing. In some embodiments, the process gas mixture may comprise between about 45.5-93.0 percent inert gas (e.g., an inert gas flow of between about 200-800 sccm). In one specific embodiment, C₄F₆ is provided at a rate of about 15 sccm; CH₂F₂ is provided at a rate of about 10 sccm; N₂ is provided at a rate of about 100 sccm; and Ar is provided at a rate of about 500 sccm.

A plasma may be formed from the process gas mixture to etch the via 211 into the low-k dielectric layer 208. In some embodiments, the plasma may be either a high density plasma (e.g., a plasma having a density that is greater than or equal to about 10¹¹ ions/cm³) or a low density plasma (e.g., a plasma having a density that is less than or equal to about 10⁹ ions/cm³). The plasma may be formed in any suitable manner, such as by coupling a radio frequency (RF) source power to the process gas to dissociate and ionize the process gas mixture. For example, between about 0-400 Watts of RF source power may be provided at a frequency of about 162 MHz. In one embodiment, about 200 Watts of RF source power is supplied at a frequency of about 162 MHz.

Once the plasma is formed from the process gas mixture, the plasma may be directed towards the low-k dielectric layer where the via is to be etched by coupling an RF bias power to the plasma. In some embodiments, between about 1500-4000 Watts of RF bias power may be provided at a frequency of about 13.56 MHz. In some embodiments, about 3000 Watts of RF bias power is supplied at a frequency of about 13.56 MHz.

The temperature and pressure of the etch chamber may be regulated during processing to maintain an environment suitable for etching the via. For example, the temperature may be controlled in a range of between about 10-40 degrees Celsius, or in some embodiments, about 25 degrees Celsius. The pressure may be maintained in range of between about 20-50 mTorr, or in some embodiments, about 30 mTorr.

After the via 211 is etched into the low-k dielectric layer 208, the remaining first mask layer 210 may be removed at 104 (as depicted in FIG. 2C). In some embodiments, the first mask layer 210 may be removed by a plasma process (e.g., ashing). In some embodiments, the plasma process may comprise one or more steps. In some embodiments, the plasma process may comprise a first step that may facilitate reduction or removal of nitrogen (N₂) and/or nitrogen-containing byproducts from the chamber and/or substrate and a second step that facilitates removal of the first mask layer 210. The plasma process thus may advantageously further reduce photoresist poisoning by reducing nitrogen or nitrogen-containing byproducts as discussed above. Moreover, the plasma process may be controlled to reduce any surface damage of the low-k dielectric material 208 during the removal process (e.g., such as by providing a low density plasma and/or low or no substrate bias).

For example, in some embodiments, the first mask layer 210 may be exposed to a first plasma at 104A. The first plasma may be formed from a first process gas including an oxygen-containing gas, such as oxygen (O₂), carbon dioxide (CO₂), or the like, mixed with at least one of a dilutant gas, such as argon (Ar) or the like, or a passivation gas, such as carbon monoxide (CO) or the like. In one specific embodiment, the first process gas comprises O₂ and Ar. In some embodiments, the oxygen-containing gas may be provided at a flow rate of between about 100-500 sccm. In some embodiments, the dilutant gas and/or the passivation gas may be provided at a flow rate of between about 100-500 sccm. In some embodiments, a flow rate ratio of the oxygen-containing gas to the dilutant gas and/or the passivation gas may be between about 1:1 and 1:5. The first plasma may be maintained for any amount of time suitable to facilitate reduction of nitrogen and nitrogen-containing byproducts. In some embodiments, the process gas may be provided for between about 10 to about 30 seconds.

In some embodiments, the first plasma formed from the first process gas may be a low density plasma, as discussed above. The plasma may be formed by coupling a radio frequency (RF) source power to the process gas to dissociate and ionize the process gas mixture. In some embodiments, up to about 1000 Watts of RF source power may be provided at a frequency of about 162 MHz. In one specific embodiment, about 500 Watts of RF source power is supplied at a frequency of about 162 MHz.

Alternatively or in combination, the first plasma may be formed and/or directed towards the first mask layer 210 by coupling an RF bias power to the plasma. In some embodiments, up to about 400 Watts of RF bias power may be provided at a frequency of about 13.56 MHz. In one embodiment, about 200 Watts of RF bias power is supplied at a frequency of about 13.56 MHz. In some embodiments, only RF source power is applied during removal of the first mask layer 210. In some embodiments, only RF bias power is applied during removal of the first mask layer 210. In some embodiments, both RF source power and RF bias power are applied during removal of the first mask layer 210.

In some embodiments, after being exposed to the first plasma, the first mask layer 210 may be removed using a second plasma at 104B. The second plasma may be formed from a second process gas that includes an oxygen-containing gas. In some embodiments, the oxygen-containing gas can be oxygen (O₂), carbon dioxide (CO₂), water vapor (H₂O), combinations thereof, or the like. The second process gas may be supplied to an etch reactor at a total gas flow between about 200-800 sccm. In some embodiments, the total gas flow may be between about 200-800 sccm, and in one embodiment the total gas flow is about 500. In one embodiment, the second process gas may comprise between about 200-800 sccm of the oxygen-containing gas. In one specific embodiment, O₂ is provided at a rate of about 500 sccm.

In some embodiments, the second plasma may be a high density plasma or a low density plasma, as discussed above. The second plasma may be formed by coupling a radio frequency (RF) source power to the process gas to dissociate and ionize the process gas mixture. In some embodiments, up to about 1000 Watts of RF source power may be provided at a frequency of about 162 MHz. In some embodiments, about 500 Watts of RF source power is supplied at a frequency of about 162 MHz.

Alternatively or in combination, the second plasma may be formed and/or directed towards the first mask layer 210 by coupling an RF bias power to the plasma. In some embodiments, up to about 400 Watts of RF bias power may be provided at a frequency of about 13.56 MHz. In one embodiment, about 200 Watts of RF bias power is supplied at a frequency of about 13.56 MHz. In some embodiments, only RF source power is applied during removal of the first mask layer 210. In some embodiments, only RF bias power is applied during removal of the first mask layer 210. In some embodiments, both RF source power and RF bias power are applied during removal of the first mask layer 210.

Once the first mask layer 210 is removed, an anti-reflective layer (ARC) 212 may be deposited into the via 211, and onto the surface of the low-k dielectric layer 208 at 106, as shown in FIG. 2D. In some embodiments, the ARC layer 212 may be an inorganic material, a silicon- oxygen- carbon- and hydrogen-containing (SiOCH) material, or other materials that do not etch well (e.g., that essentially do not etch) using an oxygen-containing plasma (such as DUO193™, available from Honeywell Advanced Microelectronic Materials). The ARC layer 212 may be deposited in any suitable manner, such as by a spin-on process.

Next, a second mask layer 214 may be deposited atop the ARC layer 212 at 108, as also shown in FIG. 2E. The second mask layer 214 may be patterned to define a trench 215.

Next, at 110, the trench 215 may be etched, as shown in FIG. 2F. The trench 215 may be etched through the second mask layer 214, through the ARC layer 212, and at least partially into the low-k dielectric layer 208. The trench 215 may be plasma etched by providing a process gas comprising a fluorine-containing gas, a nitrogen-containing gas, and an inert gas. The fluorine-containing gas may comprise tetrafluoromethane (CF₄). The nitrogen-containing gas may comprise nitrogen (N₂). The inert gas may comprise argon (Ar). In some embodiments, the process gas comprises CF₄, N₂, and Ar.

The process gas for the trench etch may be supplied to the etch reactor 302 at a total gas flow of between about 130-1050 sccm, or in some embodiments, about 460 sccm. In some embodiments, the process gas may comprise between about 11.8-90.9 percent of the fluorine-containing gas (e.g., a fluorine-containing gas flow of between about 100-300 sccm). In some embodiments, the process gas may comprise between about 3.2-60.0 percent of the nitrogen-containing gas (e.g., a nitrogen-containing gas flow of between about 30-150 sccm). In some embodiments, the process gas may comprise between about 0-82.2 percent of an inert gas (e.g., an inert gas flow of between about 0-600 sccm). In some embodiments, CF₄ may be provided at a rate of about 200 sccm; N₂ at a rate of about 60 sccm; and Ar at a rate of about 200 sccm.

A plasma may be formed from the process gas to etch the trench 215. In some embodiments, the plasma may be a high density plasma, e.g., having a density greater than or equal to about 10¹¹ ions/cm³. The plasma may be formed by coupling a radio frequency (RF) source power to the process gas to dissociate and ionize the process gases. For example, in some embodiments, up to about 1500 Watts of RF source power may be provided at a frequency of about 162 MHz. In one embodiment, about 1000 Watts of RF source power is supplied at a frequency of about 162 MHz.

In some embodiments, the plasma may be directed towards the low-k dielectric layer 208 by coupling an RF bias power to the plasma. In some embodiments, between about 300-1000 Watts of RF bias power may be provided at a frequency of about 13.56 MHz. In some embodiments, about 600 Watts of RF bias power is supplied at a frequency of about 13.56 MHz. In some embodiments, the RF bias power may be utilized without any RF source power applied.

The pressure of the etch chamber may be regulated during processing to maintain an environment suitable for etching the trench into the low-k dielectric layer 208. For example, the pressure may be maintained in range of between about 30-250 mTorr, or about 200 mTorr.

Next, at 112, the second mask layer 216 may be removed by a plasma etch, as shown in FIG. 2G. The second mask layer 216 may be removed by the same or similar process as described above with respect to removing the first mask layer 210. Alternatively, in some embodiments, the second mask layer 216 may be removed by suitable conventional processes for removing masking materials. Next, at 114, the ARC layer 214 may be removed by, for example, a wet chemical etch, as depicted in FIG. 2H. In some embodiments, the wet chemical may comprise, for example, a hydrofluoric acid solution. In some embodiments, the concentration of the hydrofluoric acid solution may range between about 1-5 percent. Next, in embodiments where a barrier layer is employed, the portion of the barrier layer 202 exposed in the via 211 may be removed at 116 by a suitable etch process to expose the underlying metal interconnect structure 204, as depicted in FIG. 2I.

Next, at 118, the dual damascene structure (e.g., the trench 215 and the via 211) may be filled with a conductive material 216, as shown in FIG. 2J. The conductive material 216 may comprise any suitable materials, for example metals, such as copper, aluminum, alloys thereof, or the like. The conductive material 216 may be deposited by any suitable process, such as plating, chemical or physical deposition, or the like. Upon filling the dual damascene structure, the process ends and the substrate may continue for further processing, for example, to complete the formation of devices being formed thereon, or otherwise as desired.

The methods described herein may be performed in any suitable etch chamber, such as the ENABLER® process chamber, available from Applied Materials, Inc., or other suitable etch chamber. For example, one suitable etch reactor is described in depth in commonly owned U.S. Pat. No. 6,853,141, issued Feb. 8, 2005 to Hoffman, et al., which is herein incorporated by reference in its entirety. As another example, FIG. 3 depicts a schematic, cross-sectional diagram of an etch reactor 302 suitable for use in performing methods of the present invention.

As shown in FIG. 3, the etch reactor 302 comprises a reactor 302 including a process chamber 310 having a conductive chamber wall 330. The chamber wall 330 is connected to an electrical ground 334 and may have a ceramic liner 331. The ceramic liner 331 facilitates in situ self-cleaning capabilities of the chamber 310, so that byproducts and residues deposited on the ceramic liner 331 can be readily removed from the liner 331 after each substrate has been processed. The process chamber 310 also includes a support pedestal 316 and an upper electrode 328 spaced apart from and opposed to the support pedestal 316. The support pedestal 316 includes an electrostatic chuck 326 for retaining a substrate 200. The electrostatic chuck 326 is controlled by a DC power supply 320. A showerhead 332 is mounted to the upper electrode 328 and is coupled to a gas panel 338 for controlling introduction of various gases into the chamber 310 (schematically shown as 350). The showerhead 332 may include different zones such that various gases can be released into the chamber 310 with different volumetric flow rates.

The support pedestal 316 is coupled to a radio frequency (RF) bias power source 322 through a matching network 324. The bias power source 322 is generally capable of producing an RF signal having a tunable frequency of from about 50 kHz to about 53.56 MHz and a bias power of about 0 to 5,000 Watts. Optionally, the bias power source 322 may be a DC or pulsed DC source. The upper electrode 328 is coupled to an RF power source 318 through an impedance transformer 319 (e.g., a quarter wavelength matching stub). The RF power source 318 is generally capable of producing an RF signal having a tunable frequency of about 360 MHz and a source power of about 0 to 5,000 Watts. In operation, the process gas 350 provided to the interior of the process chamber 310 may be ignited into a plasma 352 by application of an RF signal from the RF power source 318 to the upper electrode 328.

The reactor 302 may also include one or more coil segments or magnets 312 positioned exterior to the chamber wall 330, near a chamber lid 313. The coil segment(s) 312 are controlled by a DC power source or a low-frequency AC power source 354.

The chamber 310 is a high vacuum vessel that is coupled through a throttle valve 327 to a vacuum pump 336. During processing of the substrate 200, gas pressure within the interior of the chamber 310 is controlled using the gas panel 338 and the throttle valve 327, and maintained in a range of about 0.1 to 999 mTorr. The temperature of the chamber wall 330 is controlled using liquid-containing conduits (not shown) located in and/or around the wall. The temperature of the substrate 200 may be controlled by regulating the temperature of the support pedestal 316 via a cooling plate (not shown) having channels formed therein for flowing a coolant. In addition, a backside gas, such as a helium (He) gas from a Helium source 348, may be provided into channels disposed between the back side of the substrate 200 and grooves (not shown) formed in the surface of the electrostatic chuck 326. The electrostatic chuck 326 may also include a resistive heater (not shown) within the chuck body to heat the chuck 326 to a steady-state temperature during processing. The backside He gas is used to facilitate uniform heating of the substrate 200. The substrate 200 can be maintained at a temperature of between about 10 to about 500 degrees Celsius.

A controller 340 including a central processing unit (CPU) 344, a memory 342, and support circuits 346 for the CPU 344 is coupled to the various components of the reactor 302 to facilitate control of the processes of the present invention. The memory 342 can be any computer-readable medium, such as random access memory (RAM), read only memory (ROM), floppy disk, hard disk, or any other form of digital storage, local or remote to the reactor 302 or CPU 344. The support circuits 346 are coupled to the CPU 344 for supporting the CPU in a conventional manner. These circuits include cache, power supplies, clock circuits, input/output circuitry and subsystems, and the like. A software routine 304 or a series of program instructions may be stored in the memory 342 which, when executed by the CPU 344, causes the reactor 302 to perform, for example, processes of the present invention as described above.

FIG. 3 only shows one exemplary configuration of various types of plasma reactors that can be used to practice the invention. For example, different numbers and types of source power and bias power can be coupled into the plasma chamber using different coupling mechanisms. Using both the source power and the bias power allows independent control of a plasma density and a bias voltage of the substrate with respect to the plasma. In some applications, the source power may not be needed and the plasma may be maintained solely by the bias power. The plasma density may be enhanced by a magnetic field applied to the vacuum chamber using electromagnets driven with a low frequency (e.g., 0.1-0.5 Hertz) AC current source or a DC source. In other applications, the plasma may be generated in a different chamber from the one in which the substrate is located, and the plasma subsequently guided toward the substrate using techniques known in the art.

The aspects of the invention may be carried out in a cluster tool. Generally, a cluster tool is a modular system comprising multiple chambers which perform various functions including, but not limited to, substrate center-finding and orientation, degassing, annealing, deposition and/or etching. According to some embodiments of the present invention, a cluster tool may include a plasma etch chamber configured to perform the inventive plasma etch processes disclosed herein. The multiple chambers of the cluster tool may be mounted to a central transfer chamber which houses a robot adapted to transfer substrates between the chambers. The transfer chamber may be maintained at a vacuum condition and provides an intermediate stage for transferring substrates from one chamber to another and/or to or from one or more load lock chambers positioned at a front end of the cluster tool. One well-known cluster tool which may be adapted for use with the present invention is the Centura®, available from Applied Materials, Inc. The details of one such cluster tool, or staged-vacuum substrate processing system, is disclosed in U.S. Pat. No. 5,186,718, entitled “Staged-Vacuum Wafer Processing System and Method,” Tepman et al., issued on Feb. 16, 1993, which is incorporated herein by reference. However, the exact arrangement and combination of chambers may be altered for purposes of performing specific steps of a fabrication process, which includes the present plasma etch process.

Thus, embodiments of methods for forming dual damascene structures have been provided herein. The inventive methods advantageously limit PR scumming and/or PR poisoning that may arise during the stages of the fabrication process. For example, in some embodiments, the lower concentration of nitrogen-containing gases may advantageously limit the deposition of residual amine materials during the via etch, and thus limit PR poisoning. In some embodiments, a plasma formed from one of either RF source power or RF bias power may be utilized to remove the first mask layer, limiting damage to the surface of the low-k dielectric layer, and thus limit PR scumming during exposure and removal of the second mask layer. In some embodiments, the first mask layer may be removed using a two step plasma that facilitates reduction or removal of nitrogen and/or nitrogen-containing byproducts from the chamber and/or substrate as well as limiting damage to the surface of the low-k dielectric layer. The inventive process facilitates formation of dual damascene structures with desired critical dimensions by advantageously limiting PR poisoning and/or PR scumming that may arise during various stages of fabrication.

While the foregoing is directed to embodiments of the present invention, other and further embodiments of the invention may be devised without departing from the basic scope thereof, and the scope thereof is determined by the claims that follow.

What is claimed is:

1. A method for the fabrication of a dual damascene structure on a substrate, comprising:
plasma etching a via through a first mask layer into a low-k dielectric material disposed on a substrate;
removing the first mask layer using a process comprising:
exposing the first mask layer to a first plasma comprising an oxygen containing gas and at least one of a dilutant gas or a passivation gas; and
subsequently exposing the first mask layer to a second plasma comprising an oxygen containing gas and formed using one of either plasma bias power or plasma source power;
depositing an anti-reflective coating into the via and atop the low-k dielectric material; and
plasma etching a trench through a second mask layer formed atop the anti-reflective coating into the low-k dielectric material.

2. The method of claim 1, wherein the anti-reflective coating is an inorganic material, a silicon- oxygen- carbon- and hydrogen-containing (SiOCH) material, or a material that essentially does not etch using an oxygen containing plasma.

3. The method of claim 1, wherein plasma etching the via further comprises forming a plasma from a process gas mixture comprising a fluorocarbon gas, a nitrogen-containing gas, and an inert gas.

4. The method of claim 3, wherein the fluorocarbon gas comprises at least one of hexafluoro-1,3-butadiene (C₄F₆), octafluorocyclobutane (C₄F₈), octafluorocyclopentene (C₅F₈), hexafluorobenzene (C₆F₆), tretrafluoromethane (CF₄), or hexafluoroethane (C₂F₆).

5. The method of claim 3, wherein the process gas mixture comprises about 50-200 sccm N₂.

6. The method of claim 3, wherein the process gas mixture further comprises a hydrofluorocarbon gas including at least one of difluoromethane (CH₂F₂), trifluoromethane (CHF₃), and methyl fluoride (CH₃F).

7. The method of claim 1, wherein the oxygen-containing gas of the first plasma comprises at least one of oxygen (O₂) or carbon dioxide (CO₂).

8. The method of claim 1, wherein the dilutant gas comprises argon (Ar).

9. The method of claim 1, wherein the passivation gas comprises carbon monoxide (CO).

10. The method of claim 1, wherein the oxygen-containing gas of the second plasma comprises at least one of oxygen (O₂), carbon dioxide (CO₂), or water vapor (H₂O).

11. The method of claim 1, wherein the plasma source power used for the first plasma is provided at a magnitude of up to about 1000 Watts at a frequency of about 162 MHz.

12. The method of claim 1, wherein the plasma bias power used for the first plasma is provided at a magnitude of up to about 400 Watts at a frequency of about 13.56 MHz.

13. The method of claim 1, wherein the plasma source power used for the second plasma is provided at a magnitude of up to about 1000 Watts at a frequency of about 162 MHz.

14. The method of claim 1, wherein the plasma bias power used for the second plasma is provided at a magnitude of up to about 400 Watts at a frequency of about 13.56 MHz.

15. The method of claim 1, wherein the oxygen-containing gas of the first plasma is oxygen (O₂), and the dilutant gas is argon (Ar).

16. The method of claim 1, wherein each of the oxygen-containing gas and the dilutant gas or the passivation gas in the first plasma is provided at a flow rate of about 100-500 sccm.

17. The method of claim 1, wherein the flow rate ratio of the oxygen-containing gas to the dilutant gas or the passivation gas ranges from about 1:1-1:5.

18. The method of claim 1, wherein the oxygen-containing gas of the second plasma is oxygen (O₂).

19. The method of claim 1, wherein the oxygen-containing gas in the second plasma is provided at a flow rate of about 200-800 sccm.

20. The method of claim 1, wherein plasma etching the trench further comprises forming a plasma from a process gas mixture comprising a fluorine-containing gas, a nitrogen-containing gas, and an inert gas.

21. The method of claim 20, wherein the process gas mixture comprises CF₄, N₂, and Ar.

22. The method of claim 20, wherein plasma etching the trench further comprises providing at least one of a plasma source power at a magnitude of up to about 1500 Watts at a frequency of about 162 MHz, or a plasma bias power at a magnitude of between about 300-1000 Watts at a frequency of about 13.56 MHz.

23. A method for the fabrication of a dual damascene structure on a substrate, comprising:
plasma etching a via through a first mask layer into a low-k dielectric material disposed on a substrate using a plasma formed from a process gas mixture comprising a fluorocarbon gas, a nitrogen-containing gas, and an inert gas;
removing the first mask layer using a process comprising:
exposing the first mask layer to a first plasma comprising an oxygen-containing gas and at least one of a dilutant gas or a passivation gas; and
subsequently exposing the first mask layer to a second plasma comprising an oxygen-containing gas and formed using one of either plasma bias power or plasma source power;
depositing an anti-reflective coating into the via and atop the low-k dielectric material; and
plasma etching a trench through a second mask layer formed atop the anti-reflective coating into the low-k dielectric material using a plasma formed from a process gas mixture comprising a fluorine-containing gas, a nitrogen-containing gas, and an inert gas.
